(19) United States
(12) Patent Application Publication
(10) Pub. No.: US 2023/0211586 A1
(43) Pub. Date: Jul. 6, 2023

(54) ENCAPSULATED MICROMIRRORS FOR LIGHT REDIRECTION

(71) Applicant: Eidgenössische Materialprüfungs- und Forschungsanstalt, Dübendorf (CH)

(72) Inventor: Andre KOSTRO, Blonay (CH)

(73) Assignee: Eidgenössische Materialprüfungs- und Forschungsanstalt, Dübendorf (CH)

(21) Appl. No.: 17/761,810

(22) PCT Filed: Sep. 9, 2020
(86) PCT No.: PCT/EP2020/075172

§ 371 Date: Mar. 18, 2022

(30) Foreign Application Priority Data
Sep. 19, 2019 (EP) 19198441.8
Dec. 18, 2019 (EP) 19217638.6

(51) Int. Cl. B32B 17/10; C23C 14/50; C23C 14/20

(52) U.S. Cl. CPC B32B 17/10036; C23C 14/20; C23C 14/50; B32B 17/10779; B32B 27/32

(57) ABSTRACT

A transparent polymer film for light redirection includes a carrier layer and a structured layer in optical contact with each other. The structured layer has a multitude of curved metallic micromirrors, which are parallel to each other and encapsulated in a transparent material and separated by a periodicity distance (p) of 10 to 1000 micrometer parallel to the film surface. 50% or more of the micromirrors’ surfaces have a cross section, perpendicular to the film surface, in the form of elliptic arcs, whose radii are from the range 5 p to 25 p, and the micromirrors are arranged in a depth (d) perpendicular to the film surface from the range 1.6 p to 3.0 p, especially 2 p to 2.5 p. Glazings can be equipped with the film.

### FIELD OF THE INVENTION

The present invention relates to a polymer film with encapsulated metallic micromirrors, and to the use of such film, and windows or glazings equipped with such film, for improving daylight illumination of interior rooms, typically in buildings. The invention further relates to a method for producing said polymer film with encapsulated micromirrors, and to a metal evaporation device useful in said method.

### BACKGROUND OF THE INVENTION

The usage of daylight redirecting films (DRF) in windows may increase the depth of the room provided with natural light. Daylight redirecting films have been developed in a number of variations. US2019146126A proposes an encapsulated layer comprising microprisms separated by air channels to effect a reflection of incoming light towards the ceiling. An additional diffuser film is used to avoid glare. Similarly, films proposed in US2013265642A, US2018095196 and US2019128491 all rely on defined air gaps trapped within a transparent material. Systems of this class are translucent or even transparent at many viewing angles, but transparency is reduced by the thickness of air gaps and additional interfaces, which also reduce the overall efficiency due to reflections at the interfaces. Light redirection efficiency is reduced by the dependency of reflection on the incident angle, or when light is incident at an angle below total internal reflection angle. Glare is a problem in the highly transparent systems. The films are generally pressure sensitive and thus fitted onto existing windows by wet application of adhesives.

Existing daylight redirecting films thus have one or several of the following drawbacks: limited efficiency, insufficient glare protection, high cost, lack of transparency, unappealing aesthetic appearance, or expensive and only post construction installation (on existing installed glazing units).

The system described in WO 2014/024146 has the potential to limit solar gains in summer, however bringing this extra function reduces the overall amount of light provided by this system and reduces transparency due to the presence of vertical mirrors; the device described comprises two sets of mirrors, the first comprising parabola focusing on the second. WO/2018/083613 proposes the same film, but without vertical mirrors, for directing incoming light from the building’s facade into a horizontal light duct. Light thus redirected by parabolic mirrors is transmitted in largely horizontal direction, but also downward which is not acceptable in a window application since it would induce glare.

It has now been found that a light redirecting film based on encapsulated metallic micromirrors in the form of elliptic or especially circular arcs provides a set of advantages over the previously mentioned films. Firstly, it relies on metallic reflectors, which renders the reflector function less dependent on the angle of incidence and improves overall efficiency. Size and shape of the mirrors can be chosen within a wide range to determine the desired distribution of redirected daylight. In particular, the tilt of mirrors can be optimized to provide the best possible direction of redirection to illuminate deep areas in the room. Secondly, the encapsulation of a titled, reflecting surface within a transparent material induces a change of direction inside the material, after refraction. The light is therefore impinging on the reflector with a reduced set of angles. With present elliptic or circular curved mirrors used, a direct beam is distributed along a set of angles therefore reducing the luminance inside the room as well as glare, and increasing occupant comfort by distributing the light along the depth of the room.

A curvature with a radius equal to 5-20 times (e.g. 12.5 times) the period will induce a spread of 2 (alpha - beta), where alpha and beta are the angles defining the slope of the steeper and the flatter tangent on present micromirror, see FIG. 9. This spread is then further increased after refraction depending on the incoming angle and material refractive index. Example: Radius 12.5 p, alpha = 12.5° and beta = 0 results in a spread of 25° inside the material. For an incident angle of 45° to the horizontal (in a downward direction) on the first interface (710) and a refractive index of 1.5 both for the film and carrier glass, following snells law, the impinging angle inside the material is sin(45)/1.5 = 28.1° to the horizontal (in a downward direction). After reflection the angles are distributed between 3.1 and 28.1 degrees to the horizontal (in an upward direction). Following snells law, this results in a spread between 4.6° and 45.0° after refraction on interface 708. For higher incident angles, the micromirror can become self shadowing and the spread is thereby reduced inside the material but because the angles are respectively higher at the exit interface (708), the spread after refraction remains high.

The part of mirrors closer to incoming side are dominantly active for light with steep incident angle (high position of the sun) whereas the inner side is used only for lower incident angles. Such a progressive shape can be defined for example by the spread target incident angles and a target maximum redirection angle. As described below in more detail, the mirror may further comprise a flat part for fabrication reasons, followed by the curved shape.

Present invention thus primarily provides a polymer film optimized for daylight redirection and glare protection, which film comprises micromirrors encapsulated in a transparent medium. Present polymer film contains an array of encapsulated metallic micromirrors, characterized in that said micromirrors are curved, have a width smaller than 500 micrometer (width standing here for the dimension extending along the film’s surface normal, depth) and are spaced vertically by a distance smaller than their width.

The film is typically used for mounting on a window pane with its metallic micromirrors extending horizontally over 80% or more of the width of the transparent polymer film, which structured part of present polymer film, once mounted, typically covers the whole width of window pane in horizontal direction (FIG. 10a). In facade orientations towards the east, the film my be mounted with a clockwise rotation (FIG. 10c)proportional to the facades normal angle with respect to the south when facing the inside surface. Likewise, where the façade is oriented towards the west, the film my be mounted with a counter clockwise rotation (FIG. 10d). This rotation maximizes the number of hours where the sun is close to the plane perpendicular to the mirror direction and where the light redirection is most efficient. For an increased efficiency during hours in which the sun is far from said plan, the mirrors may follow a wave pattern instead of a line pattern (FIG. 10b). The micromirrors are curved as described below, and are arranged essentially parallel to each other. Due to their curvature, the micromirrors comprise a concave surface and a convex surface. In present polymer film mounted on the window pane, the micromirrors are essentially arranged with their concave surfaces facing upward and/or towards the inside, while their convex surfaces are facing downward and/or towards the outside, given that the outside denotes the side of incoming sunlight and the inside denotes the side, typically inside the building, which receives sunlight through present polymer film. Resulting from their curvature, the angles between the transparent polymer film’s surface normal and the tangent on the micromirror’s side foreseen for incoming light (alpha) and the tangent side foreseen for facing the interior (beta) differ from each other; typically, the micromirrors are positioned such that alpha and beta share the same algebraic sign or beta is zero, and that alpha is larger than beta (see FIG. 9); preferably, beta is from the range 0 to 15° and alpha is larger than beta but not larger than 30°.

In a similar manner, typically with its metallic micromirrors extending horizontally, present transparent polymer film may be incorporated in a rollable blind, which may be transparent, colorless or colored, or translucent with a scattering effect.

The micromirrors essentially consist of metallic layers of thickness (tm) from the range of about 20 nm to 1000 nm (preferably 40 to about 500 nm, especially preferred is a metal thickness of the curved micromirrors ranging from 40 to 100 nm), which extend into the film with depth (d, typically from the range 1.6 p to 3.0 p) perpendicularly to the film surface, and are encapsulated in the polymer film. The total thickness (f) of the transparent polymer film exceeds the depth (d) typically by 10-200% with f typically being from the range 2 p to 6 p (e.g. 0.05 to 1 mm, preferably 0.1 - 0.6 mm; see FIG. 8).

The micromirrors thus essentially consist of metallic stripes extending in a direction parallel to the film surface; they may extend in this dimension over the whole width of the polymer film (e.g. 80% or more as noted above); they may extend in a straight line or following a wave pattern and the main direction may vary from the direction foreseen for horizontal alignment by -45 to 45°. The wave pattern (FIG. 10b) is periodical and has a maximum slope of +/-45°, a period pw ranging from 0.1 p to 10p and an amplitude aw ranging from 0.05 pw to 0.25 pw.

In a preferred embodiment, especially for windows facing southward, present micromirrors essentially consist of metallic stripes extending straight in the direction foreseen for horizontal alignment on the pane (as indicated in FIG. 10a). Each micromirror is spaced from its next neighbour by the periodicity distance p, with p ranging e.g. from 10 to 500 micrometer, especially 20 to 200 micrometer (see FIG. 8). The micromirrors are bent over their depth, comprising a section forming a curved circular or elliptic arc. The curved section makes up more than 50% of the micromirror’s depth as noted below. The curved section is thus defined by its radius in case of a circular curvature, or shortest radius and longest radius from one of its focal points in case of an ellipse, and its length (i.e. square root of [h2 + d2], see FIG. 9, with h being the height and d being the depth of the micromirror as shown in FIG. 8).

The radius of the circular arcs, and each of the shortest and the longest radius of the elliptic arc, may typically be selected from the range 5 p to 20 p, or alternatively from the range 15 p to 25 p. In a preferred embodiment, the present micromirrors are curved like a section of a circle.

In general, present transparent polymer film comprises a carrier layer and a structured layer in optical contact with each other, wherein the structured layer comprises a multitude of curved metallic micromirrors encapsulated in a transparent material and separated by a periodicity distance (p) of 10 to 1000 micrometer parallel to the film surface, characterized in that 50% or more of the micromirrors surface are in the form of elliptic or circular arcs with radii from the range 5 p to 25 p, and extend in a depth (d) perpendicular to the film surface (i.e. along the film surface normal) from the range 1.6 p to 3.0 p, especially 2 p to 2.5 p.

Present micromirrors may contain sections, typically fractions of their surfaces on one end of their depth d, which are not formed as a circular arc; these surfaces typically are straight, they also may contain snapped off sections or straight sections whose extension deviates from the straight or circular surface by a sharp angle; such sections may be formed during formation of the micromirrors for technical reasons (see preparation of present micromirrors described further below). Such non-circular sections generally make up less than 50%, typically less than 40%, and preferably less than 25% of the mirror surface.

The metal (of the metallic layer forming the present micromirrors) basically may be selected from any substance showing metallic conductivity, and which is generally able to interact with light through a surface plasmon or polaron mechanism. The metal is preferably selected from the group consisting of silver, aluminum, gold, copper, platinum; especially preferred is aluminum or silver; of specific technical importance is aluminum, as explained further below in view of the present preparation method.

The precision of the curvature of present micromirrors, given as maximum deviation of its radius in percent, is generally better than 5%, typically 3% maximum, preferably 2%, especially 1% at maximum.

The term “translucent” or “translucency” as used within the present invention denotes the property of a material, typically of the substrate or an encapsulating medium, to allow light of the solar spectrum to pass through said material (general wavelength range from ca. 350 up to ca. 2500 nm); of importance for the present invention, however, is especially translucency and/or transparency for visible light, which should be able to pass equally over the whole visible range (roughly 400 to 800 nm). The term “transparent” or “transparency” as used within the present invention denotes the property of a material, typically of a polymer film or an encapsulating medium, to allow light of the solar visible spectrum to pass through said material with a minimum of scattering effects. The term generally means transparency for electromagnetic waves from the visible range of solar light, permitting transmission of at least 10%, preferably at least 30%, and more preferably at least 50% of solar radiation energy of the visible range (especially 400 to 800 nm).

The term “pane” as used within the present invention denotes the translu-cent, especially transparent, construction element of a vehicle or especially building window consisting of translucent, especially transparent, material. A glazing unit typically comprises two or more of such panes. A typical example for a transparent window pane according to the invention is a glass sheet of a glazing unit for a building window, such as sheet 710 of the insulation glass unit (IGU) schematically shown in FIG. 5.

The term “optical contact” as used within the present invention denotes the property of an interface between two materials or two layers or sheets of the same material, which causes minimal refraction or diffusion of light transmitted through said interface, especially no air inclusions.

The term “metallic layer” or “metallic micromirror” as used within the present invention essentially denotes a nearly isotropic layer generally providing metallic conductivity in both dimensions and having a thickness from the range described above to provide a reflectivity (weighted over the visible range of the spectrum with the v lambda curve to account for the sensitivity of the human eye) of at least 80%, preferably at least 90% and especially at least 95% of visible light, which thickness, however, may show variations within the range given in different sections of the micromirror as described further below.

The term “tilt” with respect to present micromirrors refers to the inclination of the beginning of the curvature (i.e. the angle beta as shown in FIG. 9).

The surface quality of the metal layers may be checked e.g. by tapping mode atomic force microscopy (AFM), Dimension 3100 close loop (Digital instrument Veeco metrology group). Both height and phase images are obtained during the scanning of samples. In general, the height image reflects the topographic change across the sample surface while the phase image reflects the stiffness variation of the materials. The mean roughness Ra represents the arithmetic average of the deviation from the center plane:

$${R}_{a} = \frac{{\sum }_{i = 1}^{N} \left|{Z}_{i} - {Z}_{c p}\right|}{N}$$

Here, Zcp is the Z value of the center plane.

The theoretical relation between reflected scattered light and surface roughness is:

$$\text{TIS} \left(\text{Rq}\right) = \text{R0} \left[1 - {\text{e}}^{∧} \left(- {\left(4 π \text{Rq cos} \text{θ} \text{i} / \text{λ}\right)}^{∧} 2\right)\right]$$

In this equation, R0 is the theoretical reflectance of the surface, Rq is the RMS roughness of the surface, θi is the angle of incidence on the surface and λ is the wavelength of light. TIS is the Total Integrated Scatter, the total amount of light scattered by a surface (Bennett & Porteus, “Relation Between Surface Roughness and Specular Reflection at Normal Incidence,”JOSA 51, 123 (1961)).

The roughness Ra of the present specular reflector with little diffusion in reflected light typically is below 150 nm (e.g. from the range 1 to 150 nm) , preferably below 50 nm; especially preferred is a metallic layer of roughness below 10 nm.

The medium encapsulating present micromirrors generally is a transparent coating material curable by radiation. A UV curable resin is preferred. In this case, the binder essentially comprises monomeric or oligomeric compounds containing ethylenically unsaturated bonds, which after application are cured by actinic radiation, i.e. converted into a crosslinked, high molecular weight form. Where the system is UV-curing, it generally contains a photoinitiator as well. Corresponding systems are described in the abovementioned publication Ullmann’s Encyclopedia of Industrial Chemistry, 5th Edition, Vol. A18, pages 451-453. The resin composition may further contain one or more stabilizers, such as a sterically hindered amine and/or a suitable UV absorber.

Dual cure systems, which are cured first by heat and subsequently by UV irradiation, or vice versa, comprise components contain ethylenic double bonds capable to react on irradiation with UV light, typically in presence of a photoinitiator.

The electromagnetic radiation thus preferably is UV light, and the radiation curable coating typically is a UV curable coating. Cure of the UV curable coating (UV lacquer) during the transfer step may be accomplished in analogy to methods described in WO 12/176126. Preferred curing wavelengths are, for example, from the short wavelength range 220 - 300 nm, especially 240 - 270 nm, and/or from the long wavelength range 340 - 400 nm, especially 350 - 380 nm, as achievable e.g. by LED curing.

The carrier film may comprise one or more layers and can be made of transparent materials such as glass and/or polymers, like polyethylene terephthalate (PET), polymethylmethacrylate (PMMA), polyethylene (PE), polystyrene (PS), polypropylene (PP), polycarbonate (PC), Polyethylene naphthalate (PEN), or cyclic olefin (co)polymers (COC/COP) or other common thermoplastics combined or not with thermoset polymers like for example polyimide (PI), cellulose triacetate (TAC). The carrier film further may comprise polyvinylbutyral (PVB), ethylene vinylacetate (EVA). The thickness of the carrier film typically is from the range 10 to 1000 micrometer, especially 40 to 400 micrometer.

The index of refraction of the transparent materials used as carrier film and its coating material often is from the range 1.4 to 1.7, typically from the range 1.4 to 1.6. In special case of birefringence (especially PET) the index of refraction along the plane of the substrate may be higher than 1.6.

Wherever mentioned, the refractive index of a material is as determined for a radiation of 589 nm (sodium D line), if not indicated otherwise.

An advantageous composite comprising the present transparent polymer film contains the layers film 1 / structured coating comprising present micromirrors / encapsulating coating / film 2, where film 1 and film 2 are typically made of EVA or PVB. Due to encapsulation of present micromirrors, a resistant composite is obtained which may be processed under application of heat and/or pressure e.g. in lamination onto glass substrates.

Use of present polymer film thus facilitates the fabrication of the glazing unit, permits its inclusion in a laminated safety glass using several layers of lamination material such as polyvinyl butyral (PVB) or ethylene-vinyl acetate (EVA), typicaly with one layer on each side of the present film as noted above; the film then adds glare protection and a very deep and horizontal part of redirected beam. Parabolic shapes which can focus sunlight impinging at a given angle or close to a given angle are not advantageous and rather induce local overheating and/or glare. Finally, the metallic coating can be tuned in thickness, enabling to tune the direct transmittance of the system, in an embodiment were the glare protection should be maximized, the coating should be thick enough to cancel direct transmittance under certain angles. The direct transmittance of such thick mirrors is almost independent on the incident angle of the reflective surface and the quantity of reflected light depends mainly on the geometrical layout of the mirror.

A further subject of the invention is a method for the preparation of present transparent polymer film comprising encapsulated curved metallic micromirrors.

Present method comprises the following steps:
i) providing a vacuum deposition chamber with a metal evaporation source and a film support (V2), wherein the film support is straight over its length (L5) and bent, in the dimension perpendicular to its length, essentially in the form of a section of a logarythmic spiral, and wherein said film support is positioned in said deposition chamber with its concave side facing the metal evaporation source (V1); and wherein said film support optionally provides active cooling;
ii) providing a transparent polymer film comprising a substrate film (carrier film) covered by a structured layer of cured or partly cured transparent coating material, which structured layer comprises parallel grooves separated by periodicity distance (p) from the range 10 to 1000 micrometer, with preferred features as described above for the present transparent polymer film with encapsulated micromirrors; the film thus provided comprising a structured side and a flat side;
iii) positioning the transparent polymer film provided in step (ii) on the film support provided in step (i) with its structured layer (grooves) facing the metal evaporation source (V1) and with main direction of grooves parallel to the film support’s length (L5); and
iv) depositing metal from the evaporation source onto the film positioned in step (iii).

The vacuum chamber provided in step (i) is equipped with one or more than one film support, e.g. 3-10 film supports, which may be mounted with their length (L5) in any desired direction, e.g. ihorizontally or vertically, The orientation is advantageously chosen in accordance with the dimension of the chamber.

The source (V1) is located approximately at the origin of the logarithmic spiral, the term “approximately” denoting a possible deviation with respect to any radius of less than 5%, preferably less than 3%.

Preferably, more than one source is placed along the direction parallel to the length (L5) of the film support (V2), e.g. 3 to 10 evaporation sources, preferably 5 to 7, per meter length (L5), to improve homogeneity and to reach the desired thickness within one load of material in the evaporation sources. An ideal distance between evaporation sources can be computed by characterizing the deposited thickness resulting from one single deposition round on a flat transparent sample (PET for example) as a function of the longitudinal position (i.e along L5). By adding up the obtained gaussian like profile at shifted intervals, the thickness obtained with multiple, spaced sources placed approximately at the spiral origin can be calculated.

The film obtained after carrying out the above process comprises inclined micromirrors following the form of the side of the groove exposed to the source (V1), preferably curved as described above; FIG. 4a gives a schematic view on the above step (iv) of the process. FIG. 4b shows an enlarged cross section of the metallized structure thus obtained, the black line schematically indicates potential metal deposition areas identified as areas 1, 3 and 4, and curved areas 2a-2c forming present curved micromirror. Present method provides a good deposition on areas 1, 2a, 2b and 2c, typically reaching a metal layer thickness from the useful range as described further above. The non-curved metal layer on area 1 is advantageously removed by a polishing step before encapsulation (v). The polishing may be realized using an eccentric polisher, e.g. with a grain 4000 disk such as Abralon™ 4000 (Mirka); in case of thick coating (tm >50), a first polishing round with a grain 3000 material is preferred. After polishing, the film is advantageously passed through one or more baths of ultrasonicated deionized water to remove debris from inside the grooves.

Metal layer thickness is typically higher on areas facing the evaporation source at closer distance (such as areas 1 and 2a in FIG. 4b), lower but still in the useful range on areas facing the evaporation source at larger distance (such as areas 2b and 2c in FIG. 4b), and lower or zero in shadow areas or areas not foreseen to receive metal (area 4 and potentially also area 3, depending on the exact dimensioning).

For obtaining higher accuracy of the metal deposition, a lower pressure is applied during the vacuum deposition process; generally, depositing at less than 10⁻³ mbar is preferred, especially at less than 5 × 10⁻⁴ mbar.

An especially preferred material for the preparation of present micromirrors is aluminum, whose use in metal evaporation processes is well established and which brings about the additional advantage that minor amounts of metal (e.g. in thickness of 5 nm or less) deposited on unwanted areas (such as areas 3 and/or 4 identified in FIG. 4b) get oxidized upon air contact after releasing the vacuum, thus forming a thin transparent layer of alumina, which does not interfere in the further function of present encapsulated micromirrors.

Encapsulation of the micromirrors obtained in the above process is achieved by application of a transparent coating material curable by radiation, preferably a material of same refractive index as the one provided in step (ii) as the coating material on the carrier film, more preferably the same material. The process of the invention thus generally comprises the further step of

v) applying a transparent coating material curable by radiation on the structured side of the film obtained in step (iv); wherein the transparent coating material is preferably a material of same refractive index as the one provided in step (ii), more preferably the same material. Typically, the material is subsequently cured by applying suitable radiation (step vi). As noted above, the coating material is preferably a material curable by UV radiation, and the radiation applied in this case is UV radiation. The film should be maintained in a flat position in this step to ensure parallelism between the film rear surface and the surface resulting from encapsulation; this can be achieved for example in a roll to roll process using an aligned dummy flat roller, or by feeding a sacrificial film against the structured film. In a batch process, the film can be maintained flat on a vacuum plate and the parallelism can be achieved with a tree point micrometric screw device.

Advantageously, the film comprising micromirrors as obtained in step (iv) described above can be laminated to a glass sheet with encapsulation of the micromirrors at the same time; the pane comprising the film may then be mounted into a glazing unit suitable for windows in vehicles and especially buildings. Priming of the glass sheet for adhesion is preferred but not mandatory depending on the material used.

Present invention thus further pertains to a method for the preparation of a glazing unit, which method comprises the preparation of a transparent polymer film containing encapsulated curved metallic micromirrors following the steps (i) to (iv) described above, and further v) coating a glass pane on one surface with a transparent coating material curable by radiation, especially in a thickness from the range 10 to 800 micrometer, arranging the transparent polymer film obtained in step (iv) on said coated surface with its structured side contacting the wet coating material, and (vi) curing the transparent coating material by applying suitable radiation as noted above.

Present invention further pertains to a metal vapor deposition device essentially as shown in FIGS. 2 and 3, comprising a vacuum chamber equipped with a film support and a metal evaporation source positioned opposite to said film support, characterised in that the film support (V2) having a length L5 and a width L2 is bent in direction of the width essentially in the form of a section of a logarythmic spiral, with its concave side facing the metal evaporation source (V1), and is suitable to hold a film in the same form of said section of the logarythmic spiral.

Preferably, the tangents on both ends of the section of the logarythmic spiral forming the sample holder V2 form, at their intersection, an angle from the range 5° to 90°, especially 10° to 50°.

Present vapor deposition device is advantageously equipped with a film feed and transportion along its length L5 to allow continous operation.

Any reference signs in the claims should not be construed as limiting the scope of the claims.

Abbreviations used in the specification or claims

| | |
|---|---|
| PMMA | the acrylic polymer Polymethylmethacrylate |
| PET | the polyester Polyethyleneterephthalate |
| PVB | the polymer Polyvinylbutyral |
| LED | light emitting diode |
| mu | micrometer |
| IGU | insulating glass unit |
| DRF | daylight redirecting film |

### EXAMPLE 1: MODELLING

The base setting for the simulation is as follows:
A south oriented room 5 m wide and 8 m deep with a ceiling height of 3 m;
the low 1 m of one façade is opaque and the remaining 2 m are glazed;
the glazed surface is split in two with a view section from 1 m to 2 m height and a daylighting section from 2 m to 3 m.

The view section is equipped with a double glazed IGU, which is purely insulating (WSG), or provides additionally a sun protective function (SSG). A daylight redirecting element cannot be placed in this section as it could induce glare to the occupant after redirection. The WSG has a visible transmission of 80% and a solar heat gain coefficient (in the following also referred to as g value / SHGC) of 63%. The SSG window has a visible transition of 40% and a solar heat gain coefficient (g value / SHGC) of 23%.

The daylight section is fitted with SSG or WSG as reference cases and with various DRF film solutions to compare performance. The comparative film (“prismatic” film further noted in the below example 3) comprises prismatic redirecting elements as shown in FIGS. 4 and 7 of US-2018-095196, but with slightly amended dimensions noted in the below table A (dimensions measured from film as purchased from 3 M).

TABLE A

Structure of prismatic film simulated compared to film shown in FIG. 7 of US-2018-095196 (A-E given in micrometer)

| | A | B | C | D | E | a | b |
|---|---|---|---|---|---|---|---|
| prismatic simulated | 40 | 48 | 9 | 12 | 49 | 22° | 8° |
| US-2018-095196 (FIG. 7 ) | 50 | 64 | 14 | 16 | 72 | 10.5° | 17° |

The room has no other side window. In all cases an indoor rollable white blind with a diffuse transmittance of 10% is used for glare protection. The blind is rolled down when the luminance exceeds 3000 cd/m2 for an occupant. The room is modeled with a reflectivity of 70% for ceilings, 50% for walls and 20% for the floor. Artificial light is provided by a dimmable LED light adapting the LED output to provide 500 lux on the work plane. A mixed strategy with 80% direct and 20% indirect artificial light is used to maximize user comfort. The LED is modelled with a final efficiency of 100 Im/ W (including dimmer, power adapter etc.).

The window systems are modeled in the Window7 software from Lawrence Berkeley National Laboratory (LBNL) combining a simulated bidirectional transmission distribution function (BTDF) for the DRF film using the standard Klems subdivision of the hemisphere into 145 patches with existing glazing from the database. The BTDFs of DRFs are simulated in Radiance using the genbsdf function using a geometrical model. A textile blind is added to model situation in which the solar protection is drawn down. The resulting combined BTDF for g value and visible transmittance is used in a Radiance simulation to compute hourly illuminance values at workplane height within the room as well as luminance for occupants to decide on the blind usage.

For the thermal simulations, the following criteria are used: adiabatic boundary to neighboring offices, U value for the wall 0.25 W m⁻² K⁻¹, medium thermal mass (inner heat storage capacity: 165 kJ/m2K), efficient ventilation (air change rate of 0.22/h) and window night cooling with an air change rate of 1.5/h in summer, 0.38/h in winter (with a switching temperature of 24° C. for the activation of night cooling), controlled indoor temperature range of 21° C. - 26° C. with active cooling and heating at a coefficient of performance (COP) of 3.5 for cooling and 3 for heating. The COP is a ratio of useful heating or cooling provided to work, internal loads are set at 9.52 W/m² to account for heat generated by appliances and occupants.

The performance criteria are daylight autonomy and final primary energy usage (using a factor 2.6 to convert from the energy required on site to the building’s effective consumption of primary energy). In particular, the daylight autonomy in the depth of the room is taken as key performance indicator.

### EXAMPLE 2: PREPARATION OF A LIGHT REDIRECTING FILM LAMINATED ON GLASS

A diamond tool as shown in FIG. 6 is prepared with a total cutting height of 100 micrometer (in main tool direction M), it has a convex curvature of 500 micrometre radius (R) on one side (thus forming a circular arc), and a flat part tilted by 12° from the tool main direction (M) on the other side. The tip of the tool (T) is a flat of 8 micrometer cross section (t), perpendicular to the tool main direction (M). The side with a convex curvature starts with an angle of 11° relatively to main direction (at tool tip) therefore it has a total included angle of 23°. The curvature of this side of the tool stops when it reaches 0° to avoid undercut during machining.

The tool is used to engrave a nickel phosphate plating on stainless steel roller with diameter of 200 mm and width of 500 mm. The roller is machined on an ultra-high precision turning lath such as the Nanotech HDL 2600 by Moore Nanotechnology systems. The diamond tool is plunged at 72 mu depth. The grooves are realized along the roller surface, nearly in the plane perpendicular to the roller axis. Successive grooves are parallel but slightly tilted with respect to this plane in order to shift the tool by exactly 40 mu at each revolution of the tool and realize a thread like a continuous groove around the roller. The spacing between grooves (periodicity) is therefore 40 micrometre. Total machined width is 325 mm.

The obtained roller is used for ultraviolet micro imprinting lithography using a UV crosslinking lacquer (Lumogen® OVD Primer 301; BASF) on a PET substrate in a roll to roll setup. The PET substrate is a 125 mu thick and 580 mm wide Hostaphan® GN 125.0 CT01B film pre-treated for optimal adhesion (Mitsubishi Polymer Film GmbH). A continuous, approximately 50 m long, cured structured film is obtained and wound up in this roll to roll replication process.

Sample sheets thus structured and cured are cut down to a suitable size of 348×1000 mm.

Sample sheets are placed on a curved substrate holder (V2, see FIG. 2 (side view) and 3 (perspective view showing only one evaporation source). The substrate holder (V2) is curved along a logarithmic spiral centered on the evaporation sources and for the angle corresponding to desired shading (ß = 18.5° for present sample; see FIG. 7). A logarithmic spiral is a curve with equation r = a e^{(θ/tan ϕ)} in polar coordinates (r, 6). It has the particularity that at any point (P) of the curve, the angle ϕ between the radial line (r; line from the origin O to P) and the tangent (t) to the curve in P is constant. a is the distance between the origin O of the spiral and the spiral at 6 = 0. For preparing the present sample, this distance (a) is set to be 300 mm, ϕ = 71.5° and θ = 0° at the horizontal. The angle between the radial line (r) and the normal (n) to the sample is therefore constant and equal to 18.5°. The section of the spiral used to define the sample holder surface is between 68.6° and 107.1°. The black curve in the upper section of FIG. 7 shows the curvature of the present sample holder (V2).

The mounted sample is placed in a vacuum physical vapor deposition chamber equipped with 6 evaporation sources placed symmetrically on both sides at 200 mm, 350 mm and 490 mm distance from the centre and above the sample and positioned as described for FIG. 2 below. Aluminum is evaporated from the sources each comprising a set of tungsten coils of 100 mm length and 15 mm diameter positioned as described for FIG. 2 and located in regular distances over the sample sheet to obtain a homogenous distribution of coating thickness. After loading the coil with 99.99% pure aluminum wires, the coil is heated by Joule heating until evaporation temperature. The process is run at a pressure of 2 × 10⁻⁴ mbar Alternatively, the process can be run at lower pressures to improve angular accuracy (e.g. down to 1 × 10⁻⁶ mbar); to compensate for diffusion of aluminium atoms at 2 × 10⁻⁴ mbar, the sample holder was tilted by elevating the higher edge of the sample holder by 30 mm.

A sample of metallized film thus obtained is investigated for the metal thickness on structure areas as identified in present FIG. 4b; results are compiled in the below table B.

TABLE B

Thickness of aluminum layer on structure

| | |
|---|---|
| Area on film structure (FIG. 4b ) | Thickness (nm) |
| 1 (top) | 109 |
| 2a (deeper end of micromirror) | 83 |
| 2b (center of micromirror) | 64 |
| 2c (front end of micromirror) | 50 |
| 3 (groove, flat snapped-off part) | 45 |
| 4 (structure’s flat back side) | < 5 (not detectable) |

Two of the resulting sheets with metallic coating are polished using a an eccentric polisher with a grain 4000 disk (Abralon™ 4000, Mirka) and subsequentially washed by passing them in two successive ultrasonicated, deionized water tanks and dried with hot air. This removes the coating in position 1.

The sheets are then assembled with transparent adhesive tape after cutting them down to 323 ×984mm to remove unstructured areas and side effects. This 646 ×984mm film is then fitted to a clear glass pane of slightly larger dimension (676×1014 mm) next to each other to cover most of the surface. The adhesion of the film is obtained by applying the same UV lacquer as in the microstructuring step described above between sheets and glass pane and curing by UV light. The glass is precoated with 400 mu thick liquid lacquer and the coated film is applied manually with the structured and coated side facing the glass. To avoid liquid lacquer to escape, a strip of hot-melt adhesive is applied on the edges to seal the film to the glass and to contain the liquid lacquer. The glass is placed on a cold metal plate (-14 to -18° C.). UV light source is used to cure the lacquer. Hereby the structure is encapsulated and fitted onto glass simultaneously, using the same UV lacquer as described above.

Subsequently, the transparent adhesive tape is removed and a transparent 1 mm thick PET plate is laminated on top of the structured film substrate. This is performed using the same liquid lacquer to remove any unevenness of the film surface and construct two perfectly parallel surfaces (air-glass interface and PET-air interface). The final stack is therefore: 1 mm PET plate, 10-300 mu cured UV lacquer, 125 mu PET film, 100-1000 mu cured UV lacquer stack with encapsulated mirrors, 4 mm glass.

The glass pane carrying the sheet thus microstructured and coated is mounted inside a double glazing, with the film comprising the encapsulated mirrors on interface # 2 (counting from the outside, see FIG. 5).

### EXAMPLE 3: MEASUREMENT OF PROTOTYPE

DIN A4 sized samples resulting from the preparation described in Example 2 are measured for characterisation.

Complex optical devices used in building facades are sometimes named Complex or Advanced Fenestration System (CFS or AFS) and are characterized by a bidirectional scattering distribution function (BSDF) and in particular the bidirectional transmission distribution function (BTDF) which influences the resulting performance on the inside of a building. This BSDF can be analytical or empirical. For complex behaviours, an empirical function can be measured using a goniophotometer to generate a matrix describing the relation between an incident direction and the resulting distribution in reflection and transmission. For visualisation the matrix is generally divided in four matrices: two for each side of the sample (front and back): one for the transmission distribution and one for reflection distribution. Therefor a goniophotometer is generally composed of a light source and a light sensor. The light source is generally collimated to measure the response of the sample at a singe incident angle. The source or the sample is generally mobile to measure a set of incident directions changing both the elevation angle (angle to the normal of the sample) and the azimuth angle (angle to the vertical plane containing the surface normal). The sensor can be a camera to measure an intensity map of reflected and transmitted distributions of light or a photoreceptor to measure the intensity in an individual reflection or transmission direction.

The DRF film of present invention is measured under 270 incident directions. The incident direction corresponds to the 145 zones of the hemisphere defined by Klems on both sides of the sample, according to CFSstandard. The used goniophotometer measures up to 100.000 directions in transmission and reflection individually, adapting the point density depending on the variability of the measured signal. This guarantees to detect very narrow peaks within the hemisphere without a very fine, full scanning. The data points aree taken with a photodetector and using a filter to account only for the visible light, and take into account the sensitivity of the human eye during the daytime (according to the photopic v-lambda curve). The large set of data points measured with this technique is then used to generate a simplified model for simulation by agglomerating measurement points into the same 145 zones in transmission and 145 in reflection. This facilitates the visualisation and enables annual simulations following the three or five phase method described by Andy Mc Neil. The extensive data set is also used to generate a more precise so-called tensor tree model for simulation of single scenes with a defined sky, this representation captures detailed peaks and is suited for a precise characterisation of glare or sun patches for example. Those models are obtained in an xml formatted file using the Radiance programmes pabobto2bsdf and bsdf2klems for the Klems representation or pabobto2bsdf and bsdf2ttree for the tensor tree representation. Both can then be viewed using the BSFDViewer software from LBNL. As described in Example 1, the Klems model can be used in the Window 7 programme to combine the measured DRF with existing glazing and assemble double or triple insulating units for example. The resulting glazing is also defined by a BSDF model that can then be used in other simulation tools.

Two samples are measured. The first sample is obtained as described in Example 2 but using only a single evaporation source placed above a sample covering only 210 mm of the 1000 mm sample holder size. The deposition is performed in three successive rounds at a pressure of 8 10⁻⁴ mbar and without polishing. All other steps except the assembly of two pieces are performed as described to fit a 210 mm by 180 mm film onto an A4 sized glass.

The second sample is obtained as described in Example 2 but using only a single evaporation source placed above a sample covering only 210 mm of the 1000 mm sample holder size. The deposition is performed in three successive rounds at a pressure of 2 10⁻⁴ mbar. All other steps, including polishing but excluding assembly of two pieces are performed as described in Example 2 to fit a 210 mm by 180 mm film onto an A4 sized glass.

TABLE C

The following table illustrates some key numbers regarding these two samples taken from this larger set of measured data

| | ALL VALUE FOR FRONT SIDE | Sample 1 | Sample 2 |
|---|---|---|---|
| at 0° incidence | Transmittance total | 41.3 % | 62.5% |
| | Transmittance direct | 33.96 % | 43.1% |
| | Max transmitted redirected peak (and angle of peak) | 2.75 % (-20°) | 6.2% (-10°) |
| at 20° incidence | Transmittance total | 63.2 % | 64.1 % |
| | Transmittance direct | 60.1 % | 47.6 % |
| | Max transmitted redirected peak (and angle of peak) | 0.6% (-30°) | 3.3 % (-10°) |
| at 40° incidence | Transmittance total | 50.1% | 55.7 % |
| | Transmittance direct | 30.1% | 15.5 % |
| | Max transmitted redirected peak (and angle of peak) | 8.7 % (+20°) | 10.6 % (+20°) |
| at 60° incidence | Transmittance total | 41.0 % | 43.5 % |
| | Transmittance direct | 3.4 % | 1.1 % |
| | Max transmitted redirected peak (and angle of peak) | 26.3 % (+40°) | 20.2% (+40°) |

The first column in the abobe table C indicates the angle of incidence for which the transmission distribution function was measured. All the presented measurements are taken on the front side and for a positive elevation angle i.e. from the upper side. The incident light is in the vertical plan perpendicular (azimuth = 0) to the sample and the angle measured between normal to the sample and light source position, positive angles are for upward direction. “Transmittance total” is the total transmittance of the sample for the given angle. Transmittance is the fraction of transmitted radiation with respect to the incident radiation. “Transmittance direct” is the transmittance in the same direction as the incident light or with a very slight deviation (less than 5° in elevation and azimuth angle). Finally, “Max transmitted redirected peak” is the largest of the 144 transmittances in a direction different from the incident direction. For those values, the corresponding angle of redirection is given, negative for downwards, positive for upwards. The angle is given in the vertical plane, perpendicular to the sample and measured relative to sample normal. The “Transmittance direct” and “Max transmitted redirected peak” values are absolute, not relative to the first.

### EXAMPLE 4: COMPARISON OF DESIGN WITH EXISTING PRODUCT

The DRF film of present invention as described in Example 2 but with a diamond turning depth of 80 mu instead of 72 mu and an ideal configuration with mirrors only on part 2 and with an ideal perfectly specular reflectance of 95% mirrors is modeled geometrically in the Radiance format and the Radiance program genbsdf was used to simulate a BTDF in Klems format with four 145×145 matrices (FILM_SIM).

A commercially available sample of a daylight redirecting film is measured as described in Example 3 to form a similar BTDF in Klems format with four 145×145 matrices (FILM_comp).

The following tables present daylighting performances simulated for two different glare protection concepts for a building at Torino (IT) following the method described in Example 1. A state of the art IGU with solar protection coating is taken from the glass data base of Window 7 and is used as reference. It has a transmittance of 40% in the visible range and 23% solar heat gain coefficient at normal incidence (SSG_4023). Using Window 7 software, an identical window is combined once with the simulated film FILM_SIM on interface #2 (DEMO) and once with the measured FILM_comp on interface #2 (comp).

The following table 1 contains results obtained for the above comparative glazing unit, and for the two present glazing assembly. The simulation is performed as described in Example 1 and yields results for a statistical year with hourly resolution. Generally, to manage glare, a blind strategy is put in place, using glare protection blinds or roller shadings. In the present case an indoor rollable white blind with a diffuse transmittance of 10% is used for glare protection. The blind is rolled down when the luminance exceeds 3000 cd/m2 for an occupant.

Along the year two different glare management strategies are used to perform this comparison for the location at Torino (IT) with a south orientation:
In winter when the sun is low, the blind is used in both the view section (bottom window) and daylight section (upper window)
In summer when the sun is high, the blinds are used only in the view section. The daylight section always remains unshaded

Table 1 shows the results for a SSG 40/23 glazing comprising a light redirecting film according to the invention (DEMO) or the commercial film (comp) in the upper area (daylighting section); for further comparison purposes, results are shown for a glazing without DRF (SSG_4023).

Tab. 1

Energy used kWh/m2 per year, daylight autonomy and hours with glare; no glare protection roller in summer

| | Primary energy needs kWh/m2 per year | | | | Daylight autonomy room depth | Office hours where luminance is exceeded for occupants during summer |
|---|---|---|---|---|---|---|
| | Cooling | Heating | Lighting | TOTAL | | |
| SSG_4023 | 12.7 | 1.1 | 14.9 | 28.7 | 51.1% | 32.9% |
| DEMO | 12.8 | 1.1 | 15.1 | 29.0 | 50.2% | 7.1% |
| comp | 12.2 | 1.1 | 16.1 | 29.4 | 45.4% | 10.0% |

It is apparent that by using the DRF of present invention, daylight autonomy can be very high while the risk of glare is kept under control: The number of office hours during the year, where luminance is exceeded, remains below 5%.

In a situation where glare occurs, the blinds are typically closed and the daylight potential is therefore lost. With the present DRF, the usage of blinds can be avoided in summer, therefore inducing energetic savings.

A further simulation of the same situation, but with the use of blinds in summer also in the daylighting part, the use of SSG_4023 glazing in the daylighting section results in 31.7% daylight autonomy in room depth, 0% office hours with glare risk but with a resulting total energy need of 34.9 kWh/m2 per year (increase of 21.6% in energy needs with respect to the situation presented in table 1).

Several location are investigated and several building types modeled. The present DRF shows a significant improvent of daylight autonomy in all cases.

### BRIEF DESCRIPTION OF FIGURES

FIG. 1 gives a schematic overview over the process for preparing present redirecting polymer film: Using a suitable microstructuring tool (A), a UV curable coating on a suitable carrier film is structured and cured (step B). The structured layer thus obtained is subjected to metal vapour under an oblique angle (C). Subsequently, another resin layer is coated, which covers the metallic microplanes and fills the gaps between the structures to provide a smooth polymer surface (step D). Other than in present examples, this figure shows roller with grating perpendicular to the direction of imprinting (cross directional microengraving).

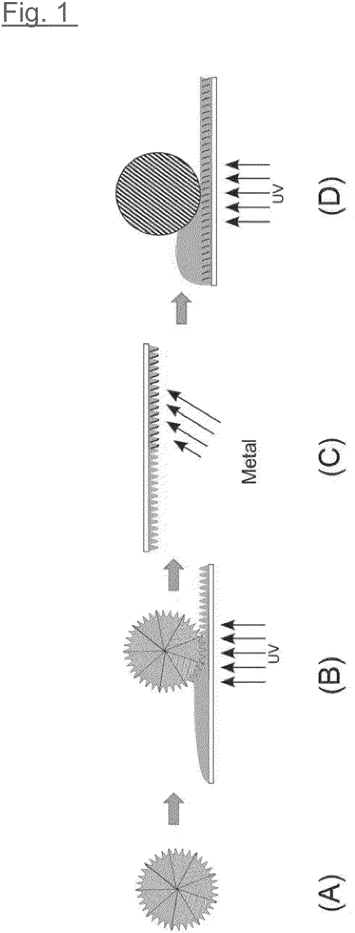

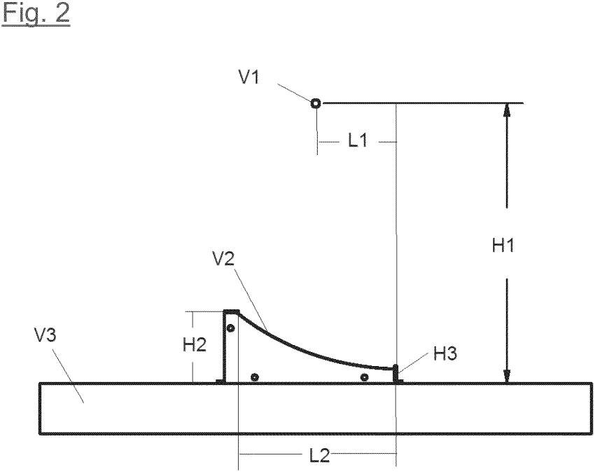

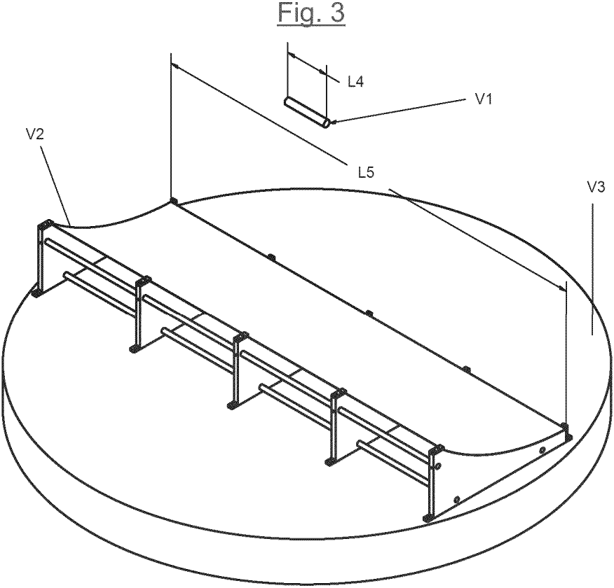

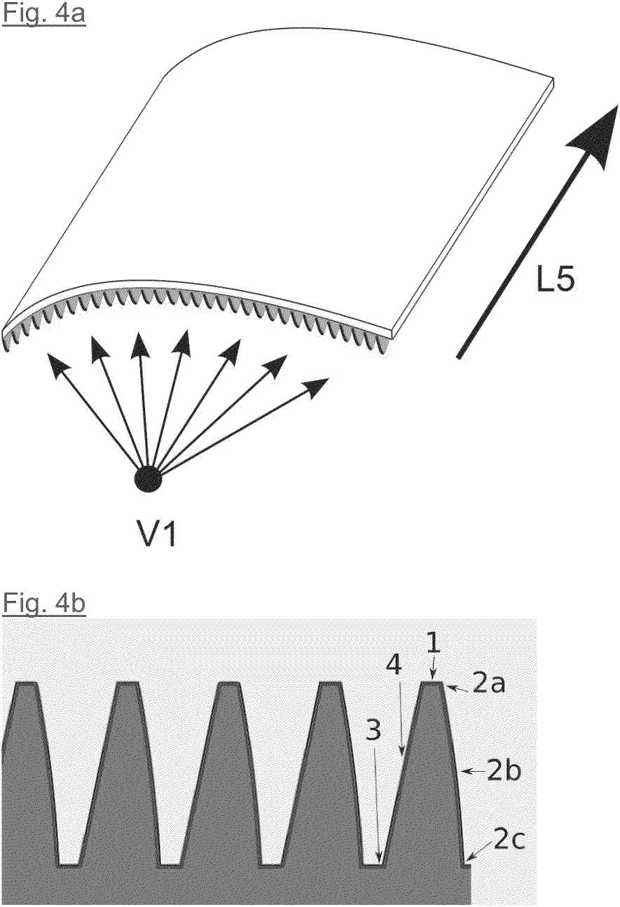

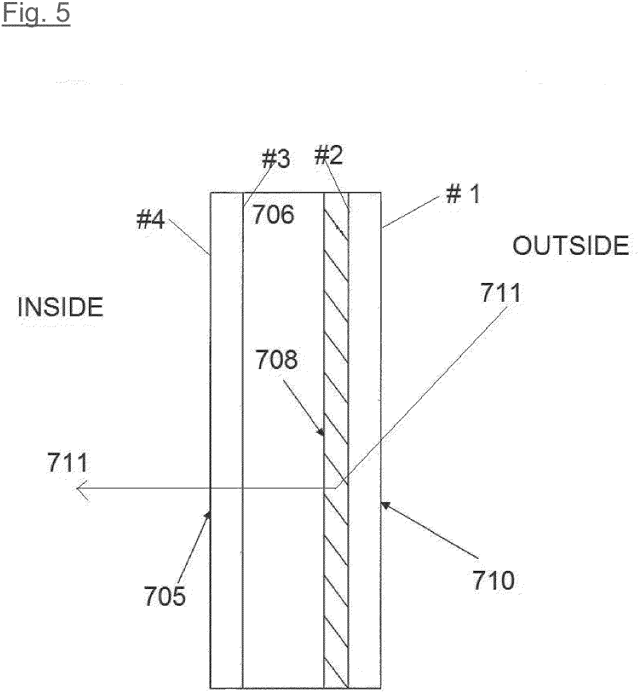

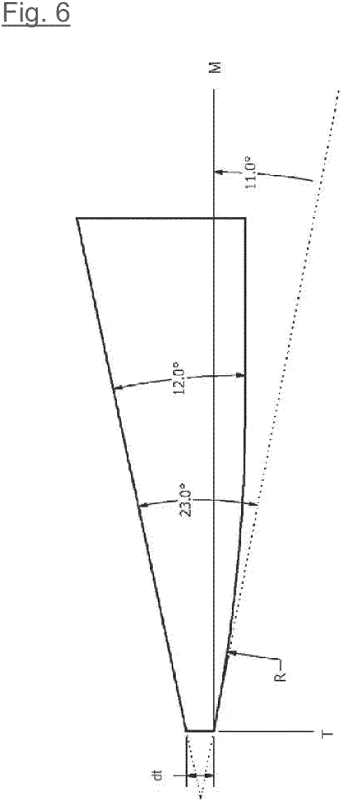

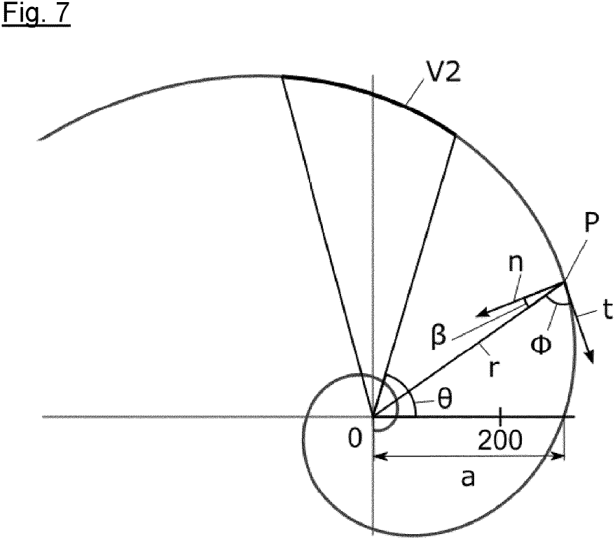

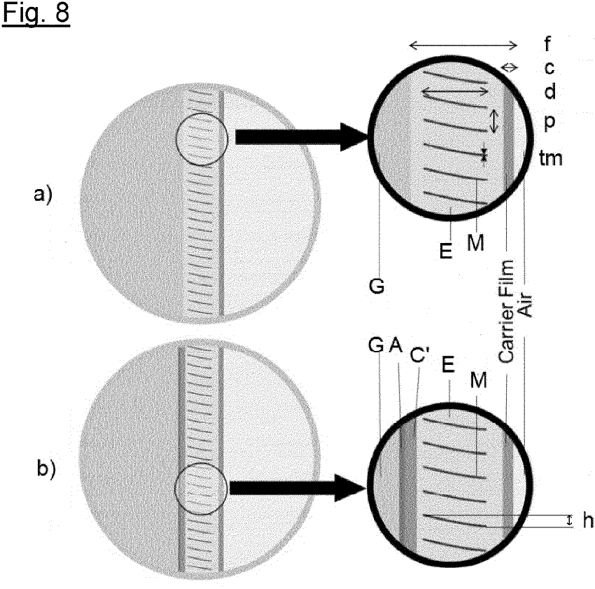

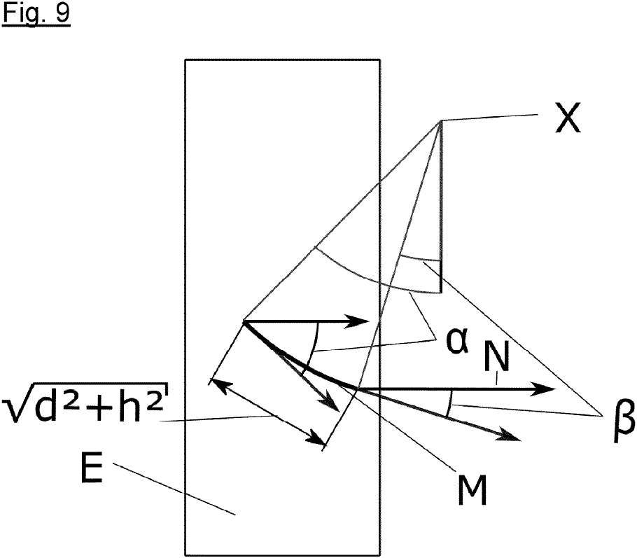

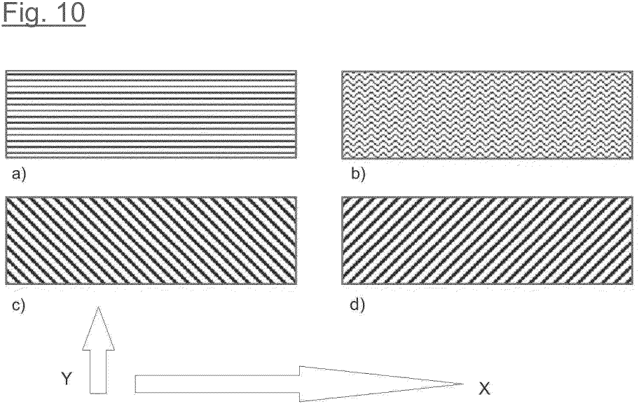

FIG. 2 shows the side view of the curved substrate holder (V2) with curvature along logaritmical spiral centered at the point of evaporation source (V1) mounted on a base plate (V3); the distances are:
560 mm (H1, vertical distance between base plate V3 and center of evaporation source V1);
139 mm (H2, vertical distance between base plate V3 and high end of sample holder V2);
25 mm (H3, vertical distance between base plate V3 and low end of sample holder V2);
158 mm (L1, horizontal distance between center of evaporation source V1 and low end of sample holder V2);
311 mm (L2, horizontal distance between high end and low end of sample holder V2).

FIG. 3 shows a perspective view of the curved substrate holder (V2) with one evaporation source (V1) mounted on a base plate (V3); the length of the evaporation source (L4) is 100.00 mm, the width (L5) of the substrate holder (V2) is 1010.00 mm.

FIG. 4a shows a perspective view on the evaporation process yielding present micromirrors; coating under oblique angle is achieved with the structured film arranged along a logarithmic spiral to obtain a constant impact angle for the aluminum evaporated from source V1 (located approximately at the spiral’s origin); the grooves of the structured film are arranged parallel to the length L5 of the sample holder.

FIG. 4b schematically shows a cross section of the metallised microstructures directly obtained in the present process as depicted in FIG. 4a forming present curved micromirrors on area 2; typically, the surfaces on present microstructures thus comprise grooves having a flat or rounded bottom (area 3); 2 lateral faces (areas 2 and 4), one thereof being curved (area 2, with its sections 2a, 2b and 2c forming the curved micromirror) while the other may be straight or rounded (area 4); and a top surface (area 1); while areas 3 and 4 obtain less or no metal coating, metal vapour is deposited in present process predominantly on areas 1 and 2, and may be mechanically removed from area 1 (polishing step).

FIG. 5 shows a schematic cross section of a double glazing comprising glass sheets 710 and 705 separated by air gap 706 mounted in a facade, with glass surfaces #1 to #4 and surface #1 facing outside the building, glass surface #4 facing inside the building, and glass surface #2 laminated with the present microstructured film (708, microstructuring indicated schematically only); 711 shows a possible light ray incoming from the outside and being redirected by present micromirrors in the film 708.

FIG. 6 shows the diamond tool comprising flat tip (T) of diameter (dt) of 8 micrometer, whose circular rounded side of radius (R) 500 micrometer deviates from the tool’s main axis (M) by 11.0° at the tip (angle indicated by dashed line), as used in present example to engrave a nickel phosphate plating on stainless steel roller.

FIG. 7 shows the logarithmic curvature of the sample holder (V2).

FIG. 8 shows cross sections of present redirecting film on glass interface #2 (according to the numbering explained for FIG. 5), mounted directly on glass G (variant (a) shown in the upper part of FIG. 8), or mounted on said interface #2 using an additional carrier layer C′ and adhesive A (variant (b) shown in the lower part of FIG. 8), and neighbouring the air gap between interfaces #2 and #3 on its other side. Enlargened sections on the right side of FIG. 8 show the film’s structuring with the carrier layer (in FIG. 8 denoted as Carrier Film) of thickness c (typically 0.05 - 0.2 mm), micromirrors M of thickness tm (typically 20 - 1000 nm), depth d (typically 0.04 - 0.5 mm) perpendicular to the film surface and height h (typically 0.05 d to 0.2 d), which micromirrors are curved with radius r (not shown in FIG. 8, r being typically from the range 5 p to 20 p) and separated by the periodicity distance p (preferably 0.02 - 0.2 mm) and encapsulated in polymeric binder E, with the total film thickness f (typically 0.1-1 mm).

FIG. 9 schematically shows the cross section of a part of present transparent polymer film comprising the encapsulating binder (E) with one circular micromirror (M), whose length is defined by its height (h) and depth (d), and whose positioning is indicated by the centre of the circular curvature (x) and the tangents on both ends of the circular section forming an angle beta (ß) at the end facing towards the inside of the room and an angle alpha (α) at the end facing the side with incoming sunlight, each with the (polymer film’s surface) plane normal (N), where alpha > beta.

FIG. 10 schematically shows windows (or blinds) equipped with present transparent polymer film indicating the orientation of present micromirrors. X denoting horizontal direction and Y denoting vertical direction. FIG. 10a shows a typical orientation of the linear metallic micromirrors extending horizontally. In windows orientated towards the east, the film may be mounted with a clockwise rotation as shown in FIG. 10c, and in windows oriented towards the west, with a counter clockwise rotation (FIG. 10d). For other orientations, the micromirrors may follow a wave pattern instead of a line pattern (FIG. 10b).

1. A transparent polymer film comprising a carrier layer and a structured layer in optical contact with each other, wherein the structured layer comprises a multitude of curved metallic micromirrors, which are parallel to each other and encapsulated in a transparent material and separated by a periodicity distance (p) of 10 to 1000 micrometer parallel to the film surface, wherein 50% or more of the micromirrors’ surfaces have a cross section, perpendicular to the film surface, in the form of elliptic arcs, whose radii are from the range 5 p to 25 p, and the micromirrors are arranged in a depth (d) perpendicular to the film surface from the range 1.6 p to 3.0 p.

2. The transparent polymer film of claim 1, wherein 50% or more of the micromirrors’ surfaces, have a cross section, perpendicular to the film surface, in the form of circular arcs, whose radius is from the range 5 p to 25 p.

3. The transparent polymer film of claim 1 wherein the periodicity distance (p) is 10 to 500 micrometer, surface.

4. The transparent polymer film of claim 1, wherein the curved metallic micromirrors show a precision of the curvature, given as maximum deviation of the radius, of 5%, at maximum, and/or a maximum surface roughness of 150 nm.

5. The transparent polymer film of claim 1, wherein the curved metallic micromirrors extend over 80% or more of the length of the transparent polymer film in one dimension.

6. A glazing unit foreseen for mounting in a building or vehicle comprising two or more glass panes, wherein one surface of one pane is for facing towards the outside of said building or vehicle and one surface of another pane is for facing towards the inside of said building or vehicle, and further comprising the transparent polymer film of claim 1 in optical contact with one or two glass panes of said glazing unit, wherein the curved metallic micromirrors extend horizontally over 80% or more of the width of the one or two glass panes, and the transparent polymer film is arranged on the surface of the pane for facing towards the inside of said building, or is arranged on a surface facing another glass pane of said glazing unit.

7. The glazing unit of claim 6, wherein the micromirrors are substantially arranged with their concave surfaces facing upward and/or towards the inside, while their convex surfaces are facing downward and/or towards the outside, with the outside being the side of incoming sunlight and the inside being the side, which receives sunlight through the polymer film.

8. A multilayer glass comprising the transparent polymer film claim 1 laminated between two glass sheets.

9. A method for the preparation of a transparent polymer film comprising encapsulated curved metallic micromirrors, the method comprising:
i) providing a vacuum deposition chamber with a metal evaporation source and a film support wherein the film support is straight over its length and bent, in the dimension perpendicular to its length, substantially in the form of a section of a logarithmic spiral, and wherein said film support is positioned in said deposition chamber with its concave side facing the metal evaporation source
ii) providing a transparent polymer film comprising a substrate film covered by a structured layer of cured or partly cured transparent coating material, which structured layer comprises parallel grooves separated by periodicity distance (p) from the range 10 to 1000 micrometer;
iii) positioning the transparent polymer film provided in step (ii) on the film support provided in step (i) with its structured layer facing the metal evaporation source and with main direction of grooves parallel to the film support’s length and
iv) depositing metal from the evaporation source onto the film positioned in step (iii).

10. The method of claim 9, wherein (v) a transparent coating material curable by radiation is applied onto the structured side of the film obtained in step (iv), and (vi) the transparent coating material applied in step (v) is subsequently cured by applying suitable radiation.

11. The method of claim 10, wherein each of the transparent coating materials applied in steps (ii) and (v) is a UV curable coating material of refractive index from the range 1.4 to 1.7.

12. A method for the preparation of a glazing unit, the method comprising:
providing a transparent polymer film produced according to the method of claim 9,
coating a glass pane on one surface with a transparent coating material curable by radiation,
arranging the transparent polymer film on said coated surface with its structured side contacting the wet coating material, and
curing the transparent coating material by applying suitable radiation.

13. A metal vapor deposition device comprising a vacuum chamber equipped with a film support and a metal evaporation source positioned opposite to said film support, wherein the film support has a length and a width is bent in direction of its width substantially in the form of a section of a logarithmic spiral, with its concave side facing the metal evaporation source and wherein said film support can hold a film in the form of said section of the logarithmic spiral.

14. A rollable blind comprising the transparent polymer film of claim 1.

15. (canceled)
